(19) United States
(12) Patent Application Publication
(10) Pub. No.: US 2025/0246989 A1
(43) Pub. Date: Jul. 31, 2025

(54) GATE DRIVE CIRCUIT AND METHOD FOR SWITCHING A SEMICONDUCTOR SWITCH

(71) Applicant: B & R Industrial Automation GmbH, Eggelsberg (AT)

(72) Inventors: Martin Schalk, Neumarkt Am Wallersee (AT); Florian Holzner, Schalchen (AT); Franz Maislinger, Mattighofen (AT); Philipp Vogel, Münchwilen (CH)

(21) Appl. No.: 18/982,504

(22) Filed: Dec. 16, 2024

(30) Foreign Application Priority Data
Jan. 31, 2024 (EP) 24155116.7

(51) Int. Cl. H02M 1/08; H02M 1/00; H02M 1/32; H02M 1/44; H02M 7/537; H03K 17/082; H03K 17/16

(52) U.S. Cl. CPC H02M 1/08; H02M 1/32; H02M 7/537; H03K 17/0828; H03K 17/168; H02M 1/0054; H02M 1/44

(57) ABSTRACT

A gate drive circuit for switching a semiconductor switch of an inverter is provided, the gate drive circuit comprising operating means designed to alternate an electrical gate quantity between a maximum gate quantity value and a minimum gate quantity value in order to switch the semiconductor switch, the operating means being further designed to, at an adjustment time point during an operating interval, adjust said maximum gate quantity value to an adjusted maximum gate quantity value, to further alternate said electrical gate quantity between said adjusted maximum gate quantity value and said minimum gate quantity value to switch the semiconductor switch.

### CROSS-REFERENCE TO RELATED APPLICATIONS

The present application claims priority to European Patent Application No. 24155116.7 filed on Jan. 31, 2024, and titled “GATE DRIVE CIRCUIT AND METHOD FOR SWITCHING A SEMICONDUCTOR SWITCH”, which is hereby incorporated by reference in its entirety.

### TECHNICAL FIELD

The present disclosure pertains to a gate drive circuit for driving an electrical gate quantity present at a gate electrode of a semiconductor switch of an inverter, the gate drive circuit comprising operating means designed to, in a pre-defined operating interval, alternate said electrical gate quantity between a maximum gate quantity value and a minimum gate quantity value to switch the semiconductor switch in order to connect or disconnect a supply voltage to an output of the inverter. The present disclosure further pertains to an assembly of an inverter, a cable and an electrical load, the inverter electrically connected to the electrical load by the cable in order to electrically supply the electrical load. Further, the present disclosure pertains to a method for operating a gate drive circuit for driving an electrical gate quantity present at a gate electrode of a semi-conductor switch of an inverter.

### BACKGROUND

In the design of modern power converters, much attention is paid to power conversion efficiency, power density, and system cost. Recently, also reliability of power electronic systems has been gaining increased attention, especially for systems with long operating hours in harsh environments.

Another aspect in today's power electronics to receive growing attention is the steady increase of switching frequencies. In this regard, significant progress has been made recently, bringing about new technologies, such as the so-called wide bandgap switches (“WBGs”), allowing for fast switching capabilities up to 10V/ns and higher, especially when compared to classical switching materials and/or classical switching technology. Unfortunately, high switching speeds are still accompanied by adverse effects, in the case of WBGs, but even more so in the case of “classical” semiconductors, such as classical insulated-gate bipolar transistors (IGBTs), classical metal-oxide-semiconductor field-effect transistor (“MOSFET”), etc. Said adverse effects range from voltage overshoot and/or voltage ringing between drain/emitter and source/collector of a switch, as well as to deteriorated electromagnetic interference properties (EMC).

These issues are known in the prior art, cf., US 2019/0074827 A1, U.S. Pat. No. 11,316,513 B2 or GB 2589296 A. Also in scientific literature, issues related to high-speed switching of semiconductor switches, particularly IGBT-switches, have been covered at length.

“A four-step control for IGBT switching improvement using an active voltage gate driver”, Chen Li et al., Wiley, IET Power Electronics, 2021, for instance, discloses a driving circuit and a corresponding method for switching an IGBT-switch, providing a step-wise modification of a gate-source voltage in the course of changing said gate-source voltage from a minimum to a maximum value for switching the IGBT, aiming at reduced overshoot of the gate-source voltage.

“A Voltage Controlled Current Source Gate Drive Method for IGBT Devices”, Lu Shu et al., IEEE, 2014, discloses a similar concept, where different modification approaches for the gate-source voltage are suggested, depending on whether the gate-source voltage is changed from a minimum to a maximum value or vice versa.

Even though the above-referenced prior art discloses highly elaborate concepts targeted at improving the performance of semiconductor switches at high switching frequencies, it turns out that these concepts do not preserve their performance over the entire operating range.

Against this background, it is an object of the present disclosure to provide an improved gate drive circuit with reduced losses, allowing for high consistency over the entire operating range of a switch or an inverter driven by the gate drive circuit. In the scope of the present disclosure, the term “gate drive circuit” is to be construed broadly, representing generally an electrical circuit capable of switching a semiconductor switch, e.g., BJTs or IGBTs or FETs, which are, e.g., known to have different pins (BCE, GCE, GDS, respectively).

### BRIEF DESCRIPTION

This object, for the gate drive circuit mentioned at the outset, in accordance with independent claim 1, is achieved in that the operating means is further designed to, at an adjustment time point during the operating interval, adjust said maximum gate quantity value to an adjusted maximum gate quantity value, to further alternate said electrical gate quantity between said adjusted maximum gate quantity value and said minimum gate quantity value to switch the semiconductor switch.

By adjusting, i.e., reducing or increasing, the maximum gate quantity value, to which the electrical gate quantity is switched consecutively in order to switch, i.e., open and close, the semiconductor switch, the switching behavior of the power semiconductors is modified. Following up on the consideration laid out before, the maximum gate quantity value may be increased in order to speed up the switching process, or it may be reduced, in order to slow down the switching process. Consequently, a largely constant EMC emission spectrum can be achieved over the entire operating range of the inverter. Also, the switching losses are reduced with respect to specific operating points. E.g., when idling or at low output currents, oftentimes high capacitive motor cable currents can be reduced by switching the semiconductors on and off slowly. Fast switching edges, on the other hand, lead to lower switching losses at high operating currents. Thus, by adapting the switching edges during operation, the present disclosure allows to consistently operate at an optimal setting regarding the switching speed used for switching the respective semiconductor switches.

Further, the above-mentioned object, for the assembly mentioned at the outset, is achieved in that the inverter present in the assembly comprises at least one semiconductor switch and a gate drive circuit according to the present disclosure.

Further, the above-mentioned object, for the method mentioned at the outset, is achieved in that the method further comprises the steps of in a pre-defined operating interval during operation of the inverter, alternating said electrical gate quantity between a maximum gate quantity value and a minimum gate quantity value in order to switch the semiconductor switch, and at an adjustment time point during the operating interval, adjusting said maximum gate quantity value to an adjusted maximum gate quantity value.

### BRIEF DESCRIPTION OF DRAWINGS

The present disclosure is described in greater detail below with reference to FIGS. 1 to 6, which show schematic and non-limiting advantageous embodiments of the present disclosure by way of example. The specific examples described herein are only used to explain the content of the present disclosure and are not intended to limit the present embodiment. The following are shown:

FIG. 1 an arrangement of a gate driver circuit, an inverter, a cable, and an electrical load.

FIGS. 2a, 2b possible profiles of the turn on behavior of an IGBT collector-emitter voltage.

FIG. 3 possible signals occurring in the gate driver circuit according to the present disclosure.

FIG. 4 an implementation of the gate driver circuit according to the present disclosure, based on a switched resistor.

FIG. 5 an implementation of the gate driver circuit according to the present disclosure, based on a push-pull converter.

FIG. 6 an advantageous implementation of the gate driver circuit according to the present disclosure employing feedback control.

### DETAILED DESCRIPTION

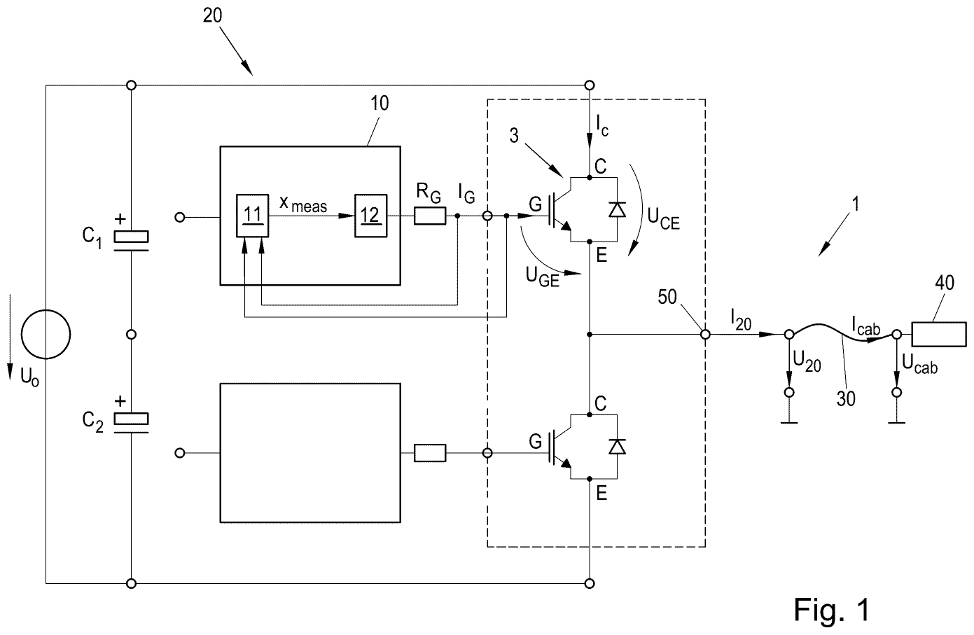

FIG. 1 shows an arrangement of a gate driver circuit 10, an inverter 20 comprising two semiconductor (power-) switches 3, a cable 30, an electrical load 40, an electrical source voltage U₀, and input capacitors C₁, C₂. Each semiconductor switch 3 has a gate electrode G, a collector electrode C, and an emitter electrode E. Such circuits and possible ways to operate such a circuit are known from the prior art, cf., e.g., U.S. Pat. No. 9,444,448 B2.

The purpose of the gate drive circuit 10 is to drive an electrical gate quantity U_{GE}, I_{G} present at a gate electrode G of the semiconductor switch 3 of the inverter 20, in order to switch the semiconductor switch 3 to eventually drive an electrical output current I₂₀ and/or an electrical output voltage U₂₀ of the inverter 20 through cable 30 to supply the load 40. To that end, the gate drive circuit 10 comprises operating means 12 designed to alternate said electrical gate quantity U_{GE}, I_{G} between a maximum gate quantity value U_{GE,max}, I_{G,max} and a minimum gate quantity value U_{GE,min}, I_{G,min} to switch the semiconductor switch 3.

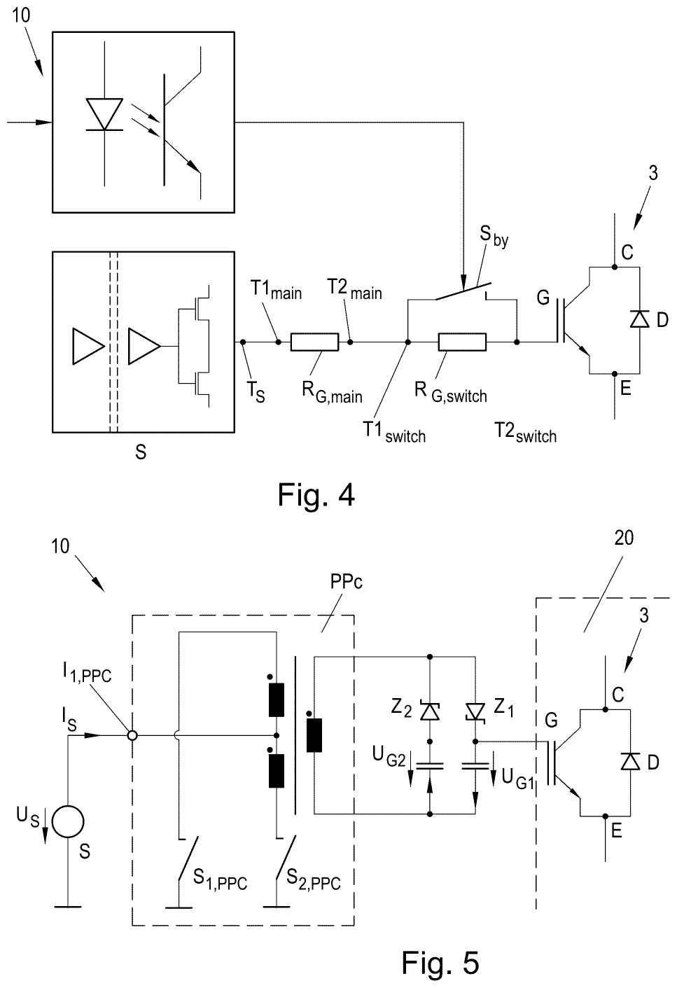

Said operating means 12 are well-known from the prior art as well, and may themselves comprise semiconductor switches and, e.g., a control unit, to provide one or more control signals for switching semiconductor switches 3 as those shown in FIG. 1. Possible implementations of the gate drive circuit 10, operating means 12, etc. are discussed in detail later, with respect to FIGS. 4 and 5. Hence, details regarding this aspect of the present disclosure are omitted for now. As will be explained in detail later, too, within the scope of this present disclosure, also the semiconductor switches 3 are by no means restricted to a specific kind of semiconductor switch, and may be implemented in the form of an insulated-gate bipolar transistor IGBT, a bipolar junction transistor BJT, or a field-effect transistor FET.

In some embodiments, said electrical gate quantity U_{GE}, I_{G} is an electrical voltage dropping from said gate electrode G to said emitter electrode E, or an electrical current flowing to or from the gate electrode G. By alternating the electrical gate quantity U_{GE}, I_{G} between a maximum gate quantity value U_{GE,max}, I_{G,max} and a minimum gate quantity value U_{GE,min}, I_{G,min} (positive gate emitter voltages are typically applied to switch on a switch 3, while negative gate emitter voltages are applied to switch it off), several well-known operating methods, such as pulse-width modulation (PWM), pulse-frequency modulation (PFM), etc., may be implemented, with the aim of generating a pulsed electrical output current I₂₀ and/or a pulsed electrical output voltage U₂₀ having a pre-defined current-time-area or voltage-time-area in a pre-defined time interval, respectively. As the fundamentals of operating an electric circuit like the one shown in FIG. 1, especially with regards to implementing methods as PWM, PFM etc., are well-known in the prior art, e.g., from US 2019/0074827 A1, U.S. Pat. No. 11,316,513 B2 or GB 2589296 A, further details in this respect are spared at this point.

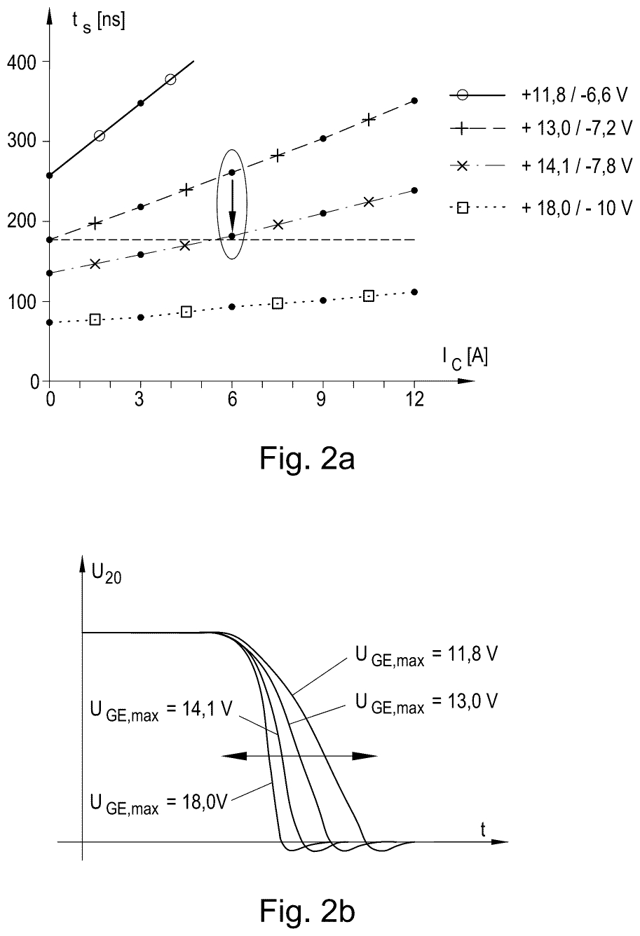

In the course of the present disclosure, it was found that certain physical quantities, most importantly the aforementioned electrical gate quantities, i.e., gate-emitter voltage U_{GE} and/or gate current I_{G} and especially their maximum values used for switching the respective semiconductor switches 3, have a crucial impact on the performance metrics of a gate drive circuit 10, such as (power) losses, EMC, dynamical and transient behavior of output quantities like U₂₀ and/or I₂₀, etc., as will be explained in the following, on the basis of FIGS. 2a and 2b

To that end, FIG. 2a first presents possible switching times t_{S} of a semiconductor switch 3, in the case shown the switching times of an IGBT, as a function of the collector current I_{C}. It was found that the time t_{S} it takes to switch the semiconductor switch 3, i.e., to complete the transition from entirely closed to entirely open, varies with the collector current I_{C} drawn from the semiconductor switch 3. Varying switching times t_{S}, however, are problematic, for several reasons. On the one hand, large switching times and thus slow switching, for obvious reasons, increases switching losses, already because the switching processes takes longer, leading to longer periods of time where both the current flowing through the switch as well as the voltage dropping over the switch are unequal zero. On the other hand, small switching times and thus high switching speeds lead to fast changes of the involved electrical quantities, leading to increased electromechanical radiation and thus worsened EMC properties. It is thus important to select an optimized switching time t_{S} for a given application, taking into account the benefits and drawbacks of an increased or reduced switching time, and maintain this switching time throughout operation.

FIG. 2b, on the contrary, shows time profiles of an output voltage U₂₀ produced by an inverter 20 as shown in FIG. 1, for different maximum values of the gate-emitter voltage U_{GE}. With a higher voltage, the gate charge required to switch the semiconductor switch 3, in this case an IGBT, is applied more quickly, thus reducing the switching time t_{S}. For the switching process, it can thus be stated that switching times t_{S} can be reduced when larger gate-emitter voltages U_{GE} are being employed.

Combining the findings presented in FIGS. 2a and 2b, one may conclude that a change in switching speed due to a changed collector current I_{C} may be compensated by adjusting the gate supply and hence the gate-emitter voltages U_{GE}. An increase in switching times at higher operating currents I_{C} can hence be compensated for by adjusting U_{GE}, in order to maintain an optimized switching time t_{S}.

In the prior art, however, especially when it comes to switching IGBT switches, permanent gate-emitter voltages with constant maximum magnitude are typically employed. Due to the fixed gate emitter voltage, the switching behavior of the IGBT modules can only be defined for a single specific operating point, leading to the aforementioned disadvantages in case of dynamic load profiles, e.g., voltage ringing between drain and source of a power semiconductor switch, increased losses, and deteriorated electromagnetic interference (EMI) properties.

To overcome these drawbacks and to provide a gate drive circuit 10 that allows for higher consistency over the operating range of an inverter 20 driven by the gate drive circuit 10, according to the present disclosure, the operating means 12 is further designed to, at an adjustment time point t_{A} in a pre-defined operating interval Tₒₚ during operation of the inverter 20, adjust said maximum gate quantity value U_{GE,max}, I_{G,max} to an adjusted maximum gate quantity value U_{max,A}, I_{max,A}, to further alternate said electrical gate quantity U_{GE}, I_{G} between said adjusted maximum gate quantity value U_{max,A}, I_{max,A} and said minimum gate quantity value U_{GE,min}, I_{G,min} to switch the semiconductor switch 3. The operating interval Tₒₚ may, e.g., be an interval selected by a user or in another fashion, in which a modification of the maximum gate quantity value U_{max,A}, I_{max,A} according to the present disclosure may be allowed. In case a modification of the maximum gate quantity value U_{max,A}, I_{max,A} shall be allowed any time during operation, the pre-defined operating interval Tₒₚ may simply of course also correspond to the on-time of the inverter 20. Also, more than one operating interval Tₒₚ may be provided during operation, so as to allow a modification during certain, selected time segments, e.g., only during low-load conditions or only during high-load conditions etc. Also the length of an operating interval Tₒₚ may of course be varied, from just a few, e.g. 10 or 50 or 100, sampling intervals, thus having a length less than a second, to more extended periods of time, e.g. having a length of several minutes or hours etc.

By adjusting, i.e., reducing or increasing, the maximum gate quantity value U_{max,A}, I_{max,A}, to which the electrical gate quantity U_{GE}, I_{G} is switched consecutively in order to switch, i.e., open and close, the semiconductor switch 3, the switching behavior of the power semiconductors 3 is modified. Following up on the consideration laid out before, the maximum gate quantity value U_{max,A}, I_{max,A} may be increased in order to speed up the switching process, or it may be reduced, in order to slow down the switching process. Consequently, a largely constant EMC emission spectrum can be achieved over the entire operating range of the inverter 20. Also, the switching losses are reduced with respect to specific operating points. E.g., when idling or at low output currents, oftentimes high capacitive motor cable currents can be reduced by switching the semiconductors on and off slowly. Fast switching edges, on the other hand, lead to lower switching losses at high operating currents. Thus, by adapting the switching edges during operation, the present disclosure allows to consistently operate at an optimal setting regarding the switching speed used for switching the respective semiconductor switches 3.

As mentioned previously, the adjusted maximum gate quantity value U_{max,A}, I_{max,A} may be smaller, e.g. 10% smaller, or 20% smaller, or 50% smaller, than the maximum gate quantity value U_{GE,max}, I_{G,max}, or the adjusted maximum gate quantity value U_{max,A}, I_{max,A} may as well be larger, e.g. 10% larger or 20% larger or 50% larger or 100% larger, than the maximum gate quantity value U_{GE,max}, I_{G,max}, depending on whether the maximum gate quantity value U_{GE,max}, I_{G,max} needs to be increased or decreased, in order to conserve an optimized switching time t_{S}.

In a particularly advantageous embodiment of the present disclosure, the gate drive circuit 10 may further comprise detecting means 11 for, at an at least one detection time point t_{D} during the operating interval Tₒₚ, detecting at least one measured value x_{meas,D} of a physical inverter quantity x representative of an operating condition assumed by the inverter 20 during the operating interval Tₒₚ. Such detecting means 11 may, e.g., be implemented in the form of a current sensor or a voltage sensor or a temperature sensor or a hall sensor, depending on the physical quantity to be measured, in some embodiments connected with appropriate signal processing devices. In some embodiments, such signal processing devices may be implemented in the form of microprocessor-based hardware, such as microcontrollers and/or integrated circuits (ASIC, FPGA).

In case a detecting means 11 is provided, the adjustment time point t_{A} may be selected as an adjustment time point t_{A} during the operating interval Tₒₚ after the detection time point t_{D}. Using the at least one measured value x_{meas,D}, the operating means may be designed to, at the adjustment time point t_{A}, adjust said maximum gate quantity value U_{GE,max}, I_{G,max} to the adjusted maximum gate quantity value U_{max,A}, I_{max,A} depending on the at least one measured value x_{meas,D} of the physical inverter quantity x.

Taking into account said measured value x_{meas,D}, it so becomes possible to, e.g., monitor a collector current by measuring the collector current measured value x_{meas,D}, define a rated current, e.g. 5A or 10A or 15A or 50A or 100A, and reduce the maximum gate quantity value U_{max,A}, I_{max,A}, in case collector current underpasses, e.g., 5% or 10% or 20% or 35% or 50% of the rated current. The measured value x_{meas,D} may also correspond to a temperature of the inverter, where a temperature threshold may be defined and the maximum gate quantity value U_{max,A}, I_{max,A} may be modified in case this threshold is underrun or surpassed, or, as in the case described above, a percentage value of such a temperature threshold is underrun or surpassed. Also, a load condition may be monitored by means of the measured value x_{meas,D}, or a parameter describing losses occurring in the inverter 20, which can again be a temperature, e.g., a temperature of a semiconductor switch 3, or a temperature of a housing of a semiconductor switch 3. Due to this flexibility, the present disclosure allows for a dynamic adaptation of the switching behavior of semiconductor switch 3, taking into account especially those quantities, that are important in a given application.

Specifically, in this embodiment of the present disclosure, the physical inverter quantity x may be selected from the group consisting of a gate or collector current I_{G}, a gate or collector current time differential dI_{G}/dt, a gate-emitter or a collector-emitter voltage U_{GE}, a gate-emitter or a collector-emitter voltage time differential dU_{GE}/dt in said semiconductor switch 3, a component temperature of a component of the inverter 20, and an electrical power processed by the inverter 20 during the operating interval Tₒₚ.

In case of the assembly 1 shown in FIG. 1, comprising an inverter 20, a power cable 30 and an electrical load 40, the inverter 20 being electrically connected to the electrical load 40 by the power cable 30 in order to electrically supply the electrical load 40, and the inverter 20 comprising at least one semiconductor switch 3 and a gate drive circuit 100 according to the present disclosure, the detecting means, in a particularly advantageous manner, may be further designed to detect an electrical cable quantity U_{cab}, I_{cab} of said power cable 30 as the at least one measured value xₘₑₐₛ. The detecting means thereby may further be designed to identify at least one cable parameter from the least one measured value xₘₑₐₛ, the cable parameter being representative of said operating condition assumed by the inverter 20 during the operating interval Tₒₚ, and the operating means may be designed to adjust said maximum gate quantity value U_{GE,max}, I_{G,max} dependent on the at least one cable parameter. Therein, the at least one cable parameter may be selected from the group consisting of a cable length, a cable resistance, a cable inductance, a cable material, a cable cross section, a cable diameter, a cable capacity.

To identify said at least one cable parameter, the gate drive circuit 10 may advantageously be designed to set the electrical gate quantity U_{GE}, I_{G} to an identification gate quantity value U_{GE,I}, I_{G,I} generating an identification output voltage on the output 50 of the inverter 20 to be fed to the cable 30 at an excitation time point t_{E}, measure at least one measured value xₘₑₐₛ of at least one electrical cable quantity x_{cable}, at an at least one detection time point t_{D} after the identification time point ti, and, identify at least one cable parameter Z_{cab} of the cable 30 from the least one measured value xₘₑₐₛ and the identification gate quantity value U_{GE,I}, I_{G,I} at an identification time point ty after the detection time point t_{D}.

In an embodiment, the at least one cable parameter Z_{cab} may be selected from the group consisting of a cable length, a cable resistance, a cable inductance, a cable material, a cable cross section, a cable diameter, a cable capacity, and in that the at least one cable quantity x_{cable} may be selected from the group consisting of a cable current I_{cable}, a cable voltage U_{cable}, a cable temperature T_{cable}, a cable magnetic field B_{cable}.

With this kind of cable identification method, it specifically becomes possible to employ an electrical gate quantity for identification purposes, which has not yet been done before. In this respect, it may further be provided to, at a multiple of, in some embodiments consecutive, excitation time points t_{E,1}, t_{E,2}, . . . , set the electrical gate quantity U_{GE}, I_{G} to a corresponding identification gate quantity values U_{GE,I,1}, U_{GE,I1}, . . . at each of said excitation time points t_{E,1}, t_{E,2}, . . . , to measure a multiple of measured values xₘₑₐₛ of the at least one electrical cable quantity x_{cable} at a multiple of detection time points t_{D,1}, t_{D,2}, . . . corresponding to said multiple of excitation time points t_{E,1}, t_{E,2}, . . . , and to identify the at least one cable parameter Z_{cab} of the cable 30 from the multiple of measured values xₘₑₐₛ and the multiple of identification gate quantity values U_{GE,I}, I_{G,I}.

However, it is to be pointed out that measuring and taking into account a physical quantity representative of an operating condition assumed by the inverter 20 during the operating interval Tₒₚ is not mandatory. On the contrary, the adjustment time point t_{A} and the adjusted maximum gate quantity value U_{max,A}, I_{max,A} may as well be pre-set before a start of operation of the inverter 20. For example, it may be known in advance that after a pre-described time between the start of operation of the inverter 20 and the adjustment time point t_{A}, a low-load condition will be assumed, such that a reduction of the maximum gate quantity value U_{max,A}, I_{max,A} is to be carried out.

Of course, in some embodiments, in case of adjusting the maximum gate quantity value U_{GE,max}, I_{G,max} depending on said measured value xₘₑₐₛ, the maximum gate quantity value U_{GE,max}, I_{G,max} may be pre-set before a start of operation of the inverter 20 and adjusted to said adjusted maximum gate quantity value U_{max,A}, I_{max,A} during operation of the inverter 20 at the adjustment time point t_{A}.

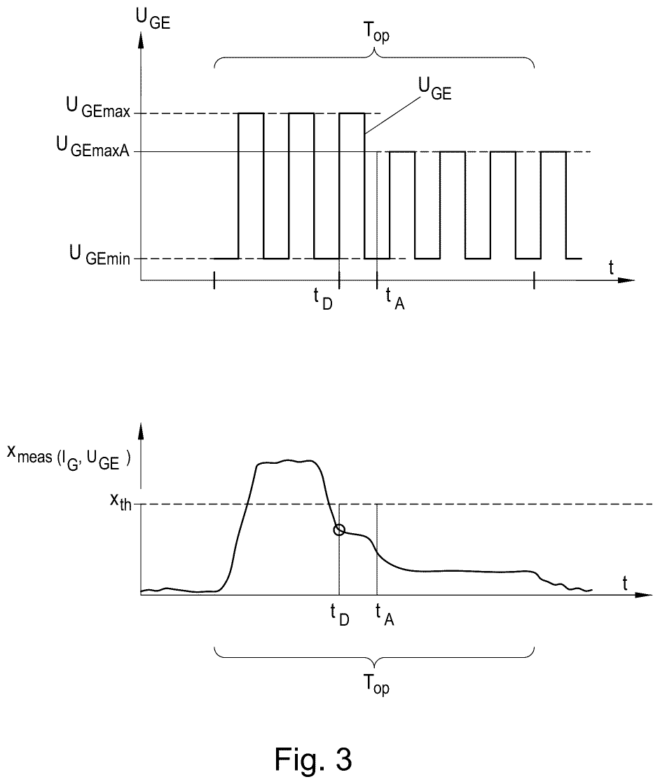

FIG. 3 further shows signals as they may occur during operation of a gate driver circuit 10 according to the present disclosure. Specifically, in the case shown in FIG. 3, operation is started at time point to, after which the measured quantity xₘₑₐₛ is increased sharply, for which a first, high maximum gate quantity value U_{GE,max}, I_{G,max} is used for alternating the electrical gate quantity U_{GE}, I_{G} to switch the semiconductor switch 3. At the detection time point t_{D}, however, a measured value x_{meas,D} of a physical inverter quantity x, which can be a current, or a temperature, or a voltage, etc., representative of an operating condition assumed by the inverter 20 during the operating interval Tₒₚ is detected. It is found that the measured value x_{meas,D} lays below a pre-set threshold value xₜₕ, leading to a reduction of the maximum gate quantity value U_{GE,max}, I_{G,max} to the smaller adjusted maximum gate quantity value U_{max,A}, I_{max,A} at the adjustment time point t_{A}. As is well-known from digital signal processing, measuring measured values x_{meas,D} may of course as well be carried on more than just one detection time point t_{D}, but in some embodiments at a multiple number of detection time points t_{D,k} which may be derived from a time discretization, in some embodiments an equidistant time discretization, where detection time points t_{D,k} are distanced by a pre-described sampling time T_{d}. In this fashion, a multiple of measured values may be consecutively compared to a pre-described threshold value, in order to immediately react to potential changes in the operation condition of the inverter 20.

As mentioned earlier, specific implementations of a gate drive circuit according to the present disclosure are shown in FIGS. 4 and 5.

Specifically, FIG. 4 shows an implementation of the gate driver according to the present disclosure, based on a switched resistor R_{G,switch}. In the implementation according to FIG. 4, an electrical supply unit S to supply said gate electrode G with an electrical supply quantity U_{S}, I_{S} to create said electrical gate quantity U_{GE}, I_{G}, a main gate resistor R_{G,main}, at least one switchable gate resistor R_{G,switch}, and a bypass switch S_{by} are provided. The supply unit S is electrically connected to the main gate resistor R_{G,main} by an electrical connection between a supply unit output terminal T_{S} and a first main gate resistor terminal T1_{,main}, the at least one switchable gate resistor R_{G,switch} is connected in series to the main gate resistor R_{G,main} by an electrical connection between a first switchable gate resistor terminal T1_{,switch} and a second main gate resistor terminal T2_{,main}, the bypass switch S_{by} is connected in parallel to the at least one switchable gate resistor R_{G,switch}, and the at least one switchable gate resistor R_{G,switch} is electrically connected to said gate electrode G by a second switchable gate resistor terminal T2_{,switch}.

In this setup, the operating means 12 is designed to switch the bypass switch S_{by}, hence bypassing the at least one switchable gate resistor R_{G,switch}, in order to adjust said maximum gate quantity value U_{GE,max}, I_{G,max} to said adjusted maximum gate quantity value U_{max,A}, I_{max,A}

The advantage of this implementation is that the switching speed can be changed quickly, i.e. high dynamics are possible without having to forego precise control of the gate supply voltage.

FIG. 5, on the contrary, presents an implementation of the gate driver according to the present disclosure based on a push-pull converter PPC. Specifically, in the implementation according to FIG. 5, an electrical supply unit S to supply said gate electrode G with an electrical supply quantity U_{S}, I_{S} to create said electrical gate quantity U_{GE}, I_{G} and a push-pull converter PPC are provided in the gate drive circuit 10. The push-pull converter PPC in this case is electrically connected to the supply unit S by an electrical connection between a supply unit output terminal T_{S} and a first push-pull converter terminal T1_{,PPC}, the at least one push-pull converter PPC is electrically connected to said gate electrode G via a second push-pull converter terminal T2_{,PPC}. In the case of FIG. 5, the operating means is designed to switch at least one switch S_{1,PPC}, in the case off FIG. 5 the two switches S_{1,PPC} and S_{2,PPC}, of the push-pull converter PPC to adjust said maximum gate quantity value U_{GE,max}, I_{G},max to said adjusted maximum gate quantity value U_{max,A}, I_{max,A}

Symmetrical control of the two switches S_{1,PPC} and S_{2,PPC} converts the primary DC voltage U_{S} into an AC voltage and transfers it to the secondary side. The rectification on the secondary side further allows to generate two gate voltages U_{G1} and U_{G2} with different signs, whereby the amplitude is determined by the transformer's turns ratio. The potential-free gate voltages on the secondary side of the transformer U_{G1} and U_{G2} are directly proportional to the primary input voltage U_{IN}:

$${U}_{G 1} ∼ \frac{{U}_{IN}}{{\ddot{u}}_{I}} - {U}_{D} = \frac{{U}_{IN}}{N 1 / N 3} - {U}_{D}$$

$${U}_{G 2} ∼ - ( \frac{{U}_{IN}}{{\ddot{u}}_{2}} - {U}_{D} ) = - ( \frac{{U}_{IN}}{N 2 / N 3} - {U}_{D} )$$

By changing the primary input voltage U_{S}, it becomes possible to adjust the resulting gate voltage for controlling the semiconductor switch 3 (IGBT or FET) without any further hardware effort. This implementation has the advantage that no hardware adjustments are necessary for adapting the maximum gate quantity value U_{GE,max}, I_{G,max}, which is beneficial especially in use-cases with high operating voltages. This also means that no additional costs occur, e.g., for further isolated signal transmissions to adapt the switching behavior in the hardware design.

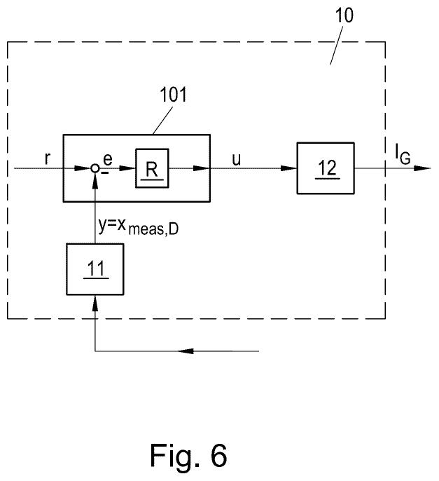

A further advantageous implementation of the gate driver circuit according to the present disclosure is depicted in FIG. 6. In FIG. 6, additionally a control unit 101 is provided in the gate drive circuit 10, the control unit 101 being designed to accept said measured value x_{meas,D} of the physical inverter quantity x as a control feedback signal y, compute a control signal u from the measured value xₘₑₐₛ, and feed said control signal u to the operating means, in order for the operating means to adjust said maximum gate quantity value U_{GE,max}, I_{G,max} according to the control signal u.

As the signal processing devices, also the control unit 101 may be implemented in the form of microprocessor-based hardware, such as microcontrollers and/or integrated circuits (ASIC, FPGA). In a particularly advantageous embodiment of the implementation with a control unit 101 from FIG. 6, said control unit 101 may be designed to consecutively accept measured values x_{meas,D} detected in the operating interval Tₒₚ, in some embodiments at the aforementioned equidistant detection time points t_{D,k}, as a control feedback signal y and continuously compute said control signal u from the control feedback signal y in accordance with a pre-defined control law R implemented in the control unit 101.

Specifically, in some embodiments said control law R may be configured to compute a control error e by comparing said feedback signal y with a pre-defined set point value r, the pre-defined set point value r corresponding to a desired operating condition of the inverter 20, and to compute said control signal u from the control error e in accordance with the control law R, the control law R being selected from the group consisting of a PID-controller, an MPC-controller, a flatness-based controller, a sliding-mode controller or even an neuronal network based controller.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A gate drive circuit for driving an electrical gate quantity present at a gate electrode of a semiconductor switch of an inverter, the gate drive circuit configured to:
in a pre-defined operating interval during operation of the inverter, alternate the electrical gate quantity between a maximum gate quantity value and a minimum gate quantity value to switch the semiconductor switch in order to connect or disconnect a supply voltage to an output of the inverter,
wherein the gate drive circuit is further configured to, at an adjustment time point during the operating interval, adjust the maximum gate quantity value to an adjusted maximum gate quantity value, to further alternate the electrical gate quantity between the adjusted maximum gate quantity value and the minimum gate quantity value to switch the semiconductor switch.

2. The gate drive circuit according to claim 1, wherein the gate drive circuit is further configured to:
at an at least one detection time point during the operating interval, detect at least one measured value (x_{meas,D}) of a physical inverter quantity (x) representative of an operating condition assumed by the inverter during the operating interval,
wherein the adjustment time point is provided as an adjustment time point during the operating interval after the detection time point, and
wherein the gate drive circuit is configured to, at the adjustment time point, adjust the maximum gate quantity value to the adjusted maximum gate quantity value depending on the at least one measured value of the physical inverter quantity.

3. The gate drive circuit according to claim 1, wherein the maximum gate quantity value is pre-set before a start of operation of the inverter and adjusted to the adjusted maximum gate quantity value during operation of the inverter at the adjustment time point.

4. The gate drive circuit according to claim 1, wherein the adjusted maximum gate quantity value is smaller than the maximum gate quantity value or in that the adjusted maximum gate quantity value is larger than the maximum gate quantity value.

5. The gate drive circuit according to claim 1, wherein an electrical supply unit to supply the gate electrode with an electrical supply quantity to create the electrical gate quantity, a main gate resistor, at least one switchable gate resistor, and a bypass switch are provided in the gate drive circuit, the supply unit electrically connected to the main gate resistor by an electrical connection between a supply unit output terminal and a first main gate resistor terminal, the at least one switchable gate resistor connected in series to the main gate resistor by an electrical connection between a first switchable gate resistor terminal and a second main gate resistor terminal, the bypass switch connected in parallel to the at least one switchable gate resistor, the at least one switchable gate resistor electrically connected to the gate electrode by a second switchable gate resistor terminal, and in that the gate drive circuit is configured to switch the bypass switch, hence bypassing the at least one switchable gate resistor, in order to adjust the maximum gate quantity value to the adjusted maximum gate quantity value.

6. The gate drive circuit according to claim 1, wherein an electrical supply unit to supply the gate electrode with an electrical supply quantity to create the electrical gate quantity and a push-pull converter are provided in the gate drive circuit, the push-pull converter electrically connected to the supply unit by an electrical connection between a supply unit output terminal and a first push-pull converter terminal, the at least one push-pull converter electrically connected to the gate electrode via a second push-pull converter terminal, and in that the gate drive circuit is configured to to switch at least one switch of the push-pull converter to adjust the maximum gate quantity value to the adjusted maximum gate quantity value.

7. The gate drive circuit according to claim 2, wherein a control unit is provided in the gate drive circuit, the control unit is configured to accept the measured value of the physical inverter quantity as a control feedback signal, compute a control signal from the measured value, and feed the control signal to the gate drive circuit, in order for the gate drive circuit to adjust the maximum gate quantity value according to the control signal.

8. The gate drive circuit according to claim 7, wherein the control unit is configured to continuously accept measured values detected in the operating interval, as a control feedback signal and continuously compute the control signal from the control feedback signal in accordance with a pre-defined control law implemented in the control unit.

9. The gate drive circuit according to claim 8, wherein the control law is configured to compute a control error by comparing the feedback signal with a pre-defined set point value, the pre-defined set point value corresponding to a desired operating condition of the inverter, and to compute the control signal from the control error in accordance with the control law.

10. The gate drive circuit according to claim 2, wherein the physical inverter quantity is selected from the group consisting of a gate or collector current, a gate or collector current time differential, a gate-emitter or a collector-emitter voltage, a gate-emitter or a collector-emitter voltage time differential in the semiconductor switch, a component temperature of a component of the inverter, and an electrical power processed by the inverter during the operating interval.

11. The gate drive circuit according to claim 1, wherein the gate drive circuit, in order to adjust the maximum value maximum gate quantity value, is configured to modify at least one value selected from the group consisting of a gate resistance, a gate power supply voltage, a gate current, a gate-emitter capacitance and a gate-emitter capacitance.

12. The gate drive circuit according to claim 1, wherein the adjustment time point and the adjusted maximum gate quantity value are pre-set before a start of operation of the inverter.

13. An assembly comprising an inverter, a power cable and an electrical load, an output of the inverter is electrically connected to the electrical load by the power cable in order to electrically supply the electrical load, and the inverter comprising at least one semiconductor switch and a gate drive circuit for driving an electrical gate quantity present at a gate electrode of a semiconductor switch of the inverter, the gate drive circuit configured to:
in a pre-defined operating interval during operation of the inverter, alternate the electrical gate quantity between a maximum gate quantity value and a minimum gate quantity value to switch the semiconductor switch in order to connect or disconnect a supply voltage to the output of the inverter,
wherein the gate drive circuit is further configured to, at an adjustment time point during the operating interval, adjust the maximum gate quantity value to an adjusted maximum gate quantity value, to further alternate the electrical gate quantity between the adjusted maximum gate quantity value and the minimum gate quantity value to switch the semiconductor switch.

14. The assembly according to claim 13, wherein:
the gate drive circuit is configured to detect an electrical cable quantity of the power cable as the at least one measured value,
the gate drive circuit is further configured to identify at least one cable parameter from the least one measured value, the cable parameter representative of the operating condition assumed by the inverter during the operating interval, and
the gate drive circuit is configured to adjust the maximum gate quantity value dependent on the at least one cable parameter.

15. A method for operating a gate drive circuit for driving an electrical gate quantity present at a gate electrode of a semiconductor switch of an inverter, comprising:
in a pre-defined operating interval during operation of the inverter, alternating the electrical gate quantity between a maximum gate quantity value and a minimum gate quantity value in order to switch the semiconductor switch; and
at an adjustment time point during the operating interval, adjusting the maximum gate quantity value to an adjusted maximum gate quantity value.

16. The gate drive circuit according to claim 9, wherein the control law is selected from the group consisting of a PID-controller, an MPC-controller, a flatness-based controller, a sliding-mode controller or a neuronal network based controller.

17. The gate drive circuit according to claim 8, wherein the control unit is configured to continuously accept measured values detected in the operating interval at equidistant detection time points as the control feedback signal and continuously compute the control signal from the control feedback signal in accordance with the pre-defined control law implemented in the control unit.
